(19) United States
(12) Patent Application Publication
(10) Pub. No.: US 2019/0363150 A1
(43) Pub. Date: Nov. 28, 2019

(54) DISPLAY DEVICE

(71) Applicant: Sharp Kabushiki Kaisha, Sakai City, Osaka (JP)

(72) Inventors: Akira NOMURA, Sakai City (JP); Taketoshi NAKANO, Sakai City (JP)

(21) Appl. No.: 16/066,816

(22) PCT Filed: Mar. 29, 2017
(86) PCT No.: PCT/JP2017/012892

§ 371 Date: Jun. 28, 2018

(51) Int. Cl. H01L 27/32; H01L 51/52

(52) U.S. Cl. CPC H01L 27/3276; H01L 51/5225; H01L 51/5209

(57) ABSTRACT

In an organic EL display device, each of high level power source lines has both end portions smaller from a first end portion side toward a second end portion side in at least a part of a section ranging from the first end portion on a side supplied with a high level power source voltage (ELVDD) from a power source circuit to the second end portion. Accordingly, variations in luminance of pixels are reduced.

### TECHNICAL FIELD

The disclosure relates to a display device.

### BACKGROUND ART

In an electroluminescence (EL) panel in PTL 1, a plurality of scan electrodes connected to a scan driver IC and a plurality of drive electrodes connected to a drive driver IC intersect each other. It is then assumed that a drive electrode on a side close to the scan driver IC has a relatively great wiring resistance, and a drive electrode on a side far from the scan driver IC has a relatively small wiring resistance.

According to PTL 1, such a configuration is considered to reduce distortion of a waveform being a rectangular wave of output voltage from the drive driver IC, which is caused by a wiring resistance of the scan electrodes connected to the scan driver IC.

### CITATION LIST

### Patent Literature

PTL 1: JP 2001-83934 A

### SUMMARY

### Technical Problem

In various display devices such as an organic EL display device, a power source circuit that supplies a constant voltage for generating a voltage according to a gray scale of each pixel is also disposed, in addition to the scan driver IC and the drive driver IC. A plurality of power source lines are connected to the power source circuit, and each of the power source lines extend in a direction away from the power source circuit.

Then, a voltage is adjusted for every pixel from a constant voltage supplied to each of the power source lines, and such an adjusted voltage is supplied to each pixel electrode.

In an organic EL display device 101 illustrated in FIG. 8, a driver 102, on which a power source circuit for supplying a constant voltage to each pixel is mounted, is disposed to be adjacent to a display region 105 including pixels arranged in a matrix. In the display region 105, although not illustrated, each of power source lines is disposed such that one end portion is connected to the driver 102 and each of the power source lines extends in a direction away from the driver 102 toward another end portion.

Areas of light emitting portions that are each included in a pixel and that emit light by a voltage applied from a pixel electrode are all made to have the same sizes from a side close to the driver 102 to a side far from the driver 102. Widths of the power source lines are also made to have the same sizes from the side close to the driver 102 to the side far from the driver 102. Then, in the power source lines, a resistance value increases near the side far from the driver 102 more than near the side close to the driver 102 because a wiring resistance is added up, so that a voltage value supplied to the pixel electrode increases. As a result, luminance of pixels decreases in a region Z in the display region 105 on the side far from the driver 102. This leads to variations in luminance in the whole display region 105.

In PTL 1, no consideration is given to a wiring resistance of the power source line. For example, in a case where, out of both end portions of the power source line, a resistance value near an end portion on a side close to the power source circuit (end portion on a side supplied with voltage) is relatively great, a value of a constant voltage supplied to every power source line becomes unstable and variations in luminance of the pixels thus increase.

The disclosure has been made in view of the above-mentioned issues in the related art, and has an object to provide a display device in which variations in luminance of pixels are reduced.

### Solution to Problem

To solve the above-mentioned problems, a display device according to one aspect of the disclosure is a display device including a display region including pixels disposed in a row direction and a column direction, each of the pixels including a first electrode and a second electrode facing each other with an electro-optic element interposed between the first electrode and the second electrode. The display device includes: a power source circuit serving as a supply source of a voltage supplied to the first electrode; power source lines connected to the power source circuit to be supplied with a constant voltage from the power source circuit; and pixel circuits respectively disposed in the pixels, each of the pixel circuits including the electro-optic element, the first electrode, and the second electrode, each of the pixel circuits being configured to be supplied with the constant voltage from at least one of the power source lines and to control a signal to be given to the electro-optic element. Each of the power source lines extends along the pixels aligned in the row direction or the column direction, and includes a first end portion being on a first end portion side to be supplied with the constant voltage from the power source circuit and a second end portion being on a second end portion side opposite to the first end portion, and a resistance value per unit length in each of the power source lines is reduced from the first end portion side to the second end portion side in at least a part of a section ranging from the first end portion to the second end portion.

To solve the above-mentioned problems, a display device according to one aspect of the disclosure is a display device including a display region including pixels disposed in a row direction and a column direction, each of the pixels including a first electrode and a second electrode facing each other with an electro-optic element interposed between the first electrode and the second electrode. The display device includes: a power source circuit serving as a supply source of a voltage supplied to the first electrode; power source lines connected to the power source circuit to be supplied with a constant voltage from the power source circuit; and pixel circuits respectively disposed in the pixels, each of the pixel circuits including the electro-optic element, the first electrode, and the second electrode, each of the pixel circuits being configured to be supplied with the constant voltage from at least one of the power source lines and to control a signal to be given to the electro-optic element. Each of the power source lines extends along the pixels aligned in the row direction or the column direction, and includes a first end portion being on a first end portion side to be supplied with the constant voltage from the power source circuit and a second end portion being on a second end portion side opposite to the first end portion, and out of the pixels aligned to be adjacent to at least a part of a section ranging from the first end portion to the second end portion in each of the power source lines, an area of the electro-optic element included in a pixel of the pixels on the second end portion side is greater than an area of the electro-optic element included in a pixel of the pixels on the first end portion side.

### Advantageous Effects of Disclosure

According to one aspect of the disclosure, there is an effect of obtaining a display device in which variations in luminance of pixels are reduced.

### BRIEF DESCRIPTION OF DRAWINGS

FIG. 1 is a plan view illustrating a configuration of an organic EL display device according to a first embodiment of the disclosure.

FIG. 2 is a cross-sectional view illustrating a configuration of the organic EL display device according to the first embodiment of the disclosure.

FIG. 3 is a diagram illustrating a configuration of a pixel circuit of the organic EL display device according to the first embodiment of the disclosure.

FIG. 4 is a plan view illustrating a configuration of an organic EL display device according to a second embodiment of the disclosure.

FIG. 5 is a plan view illustrating a configuration of an organic EL display device according to a third embodiment of the disclosure.

FIG. 6 is a plan view illustrating a configuration of an organic EL display device according to a fourth embodiment of the disclosure.

FIG. 7 is a diagram illustrating a configuration of a power source line of an organic EL display device according to a fifth embodiment of the disclosure.

FIG. 8 is a diagram illustrating a configuration of an organic EL display device in the related art.

### DESCRIPTION OF EMBODIMENTS

### First Embodiment

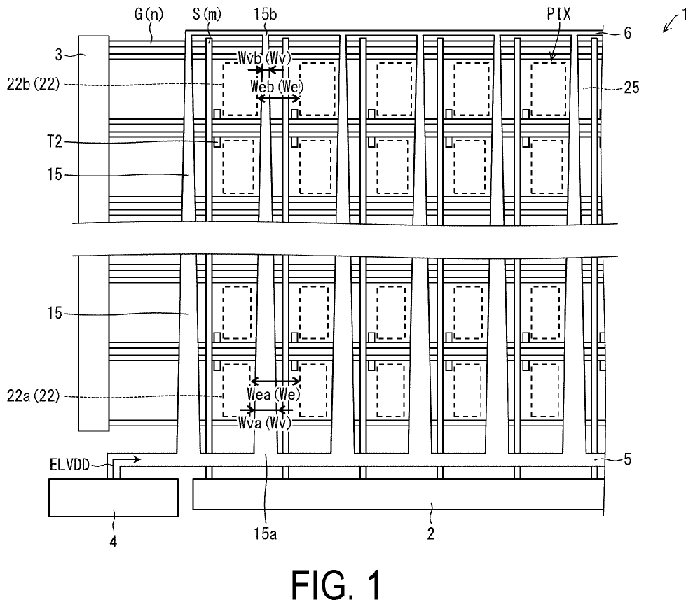

A first embodiment of the disclosure will be described on the basis of FIG. 1 to FIG. 3.

Note that it will be described by taking an organic EL display device as an example of a display device according to the first embodiment. However, the display device according to the first embodiment can be any display device including a plurality of electro-optic elements and is not particularly limited to the organic EL display device. The electro-optic element mentioned above includes an electro-optic element having luminance or a transmittance controlled by current and an electro-optic element having luminance or a transmittance controlled by voltage. The display device including an electro-optic element controlled by current includes an organic ElectroLuminescence (EL) display device including an Organic Light Emitting Diode (OLED), a Quantum dot Light Emitting Diode (QLED) display device including an EL display QLED such as an inorganic EL display device including an inorganic light emitting diode, or the like. Furthermore, the display device including an electro-optic element controlled by voltage includes a liquid crystal display device or the like. The same applies to a second embodiment and following embodiments.

### Overall Configuration of Organic EL Display Device 1

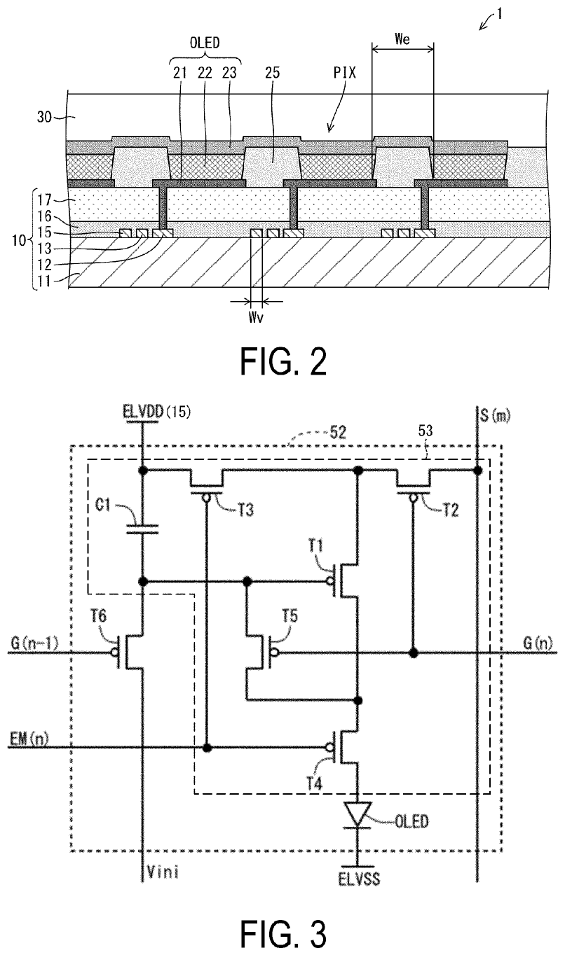

An overall configuration of an organic EL display device (display device) 1 will be described with reference to FIGS. 1 and 2. FIG. 1 is a plan view illustrating a configuration of an organic EL display device 1 according to a first embodiment of the disclosure. FIG. 2 is a cross-sectional view illustrating a configuration of the organic EL display device 1 according to the first embodiment of the disclosure.

As illustrated in FIGS. 1 and 2, the organic EL display device 1 includes a display region being a region for displaying an image by pixels PIX arranged in a matrix. Furthermore, the organic EL display device 1 includes a frame region (not illustrated) being a peripheral region that surrounds the display region and does not include the pixels PIX arranged therein. The organic EL display device 1 may be a display device having flexibility (display device that can be curved) or may be a display device having no flexibility (display device that cannot be curved).

The organic EL display device 1 has a configuration in which a first electrode 21, a light emitting portion (electro-optic element) 22, an edge cover 25, a second electrode 23, and a sealing layer 30 are formed on a Thin Film Transistor (TFT) substrate 10. The organic EL display device 1 includes a drive circuit, which is not illustrated, for driving each of the pixels PIX. The organic EL display device 1 may further include a touch panel.

The TFT substrate 10 includes a support body 11, transistors T2, data lines S(m), scanning signal lines G(n), high level power source lines 15, a passivation film 16, and an interlayer insulating film 17. Note that m and n are natural numbers.

The support body 11 is made of a transparent insulating material such as a plastic film and a glass substrate. In a case where the organic EL display device 1 is formed as a display device having flexibility, the support body 11 may be made of a plastic film. Alternatively, in a case where the organic EL display device 1 is formed as a display device having no flexibility, the support body 11 may be made of a glass substrate.

The transistors T2, the data lines S(m), the scanning signal lines G(n), and the high level power source lines 15 are formed on the support body 11.

Each transistor T2 is a transistor that controls writing of a data signal from corresponding data line S(m) by a scanning signal from the corresponding scanning signal line G(n). Each transistor T2 is formed in each of the pixels PIX on the support body 11 or through another layer. Each transistor T2 includes a semiconductor layer, a gate electrode, a drain electrode, and a source electrode, which are not illustrated.

Each data line S(m) is formed in the same layer as the drain electrode and the source electrode of the transistor T2, and is connected to the source electrode. The data lines S(m) include m data lines formed in parallel with each other. Each scanning signal line G(n) is formed in the same layer as the gate electrode of the transistor T2, and is connected to the gate electrode. The scanning signal lines G(n) include n scanning signal lines formed in parallel with each other.

The data lines S(m) and the scanning signal lines G(n) intersect each other. The pixels PIX are formed by being partitioned by the data lines S(m) and the scanning signal lines G(n).

A source driver 2 is connected to one of end portions of each data line S(m), and a gate driver is connected to one of end portions of each scanning signal line G(n).

The high level power source lines 15 are formed in parallel with the data lines S(m) in the first embodiment. The high level power source lines 15 also includes n high level power source lines formed in parallel with each other. Each high level power source line 15 is a wire for supplying a high level power source voltage ELVDD being a constant voltage to each of the pixels PIX.

Each of the high level power source lines 15 includes a first end portion 15a and a second end portion 15b, which are both end portions. Each of first end portions 15a is connected to a power source bus line 5, so that the first end portions 15a adjacent to each other are connected to each other. In other words, each of the first end portions 15a is an end portion on a side close to the power source bus line 5. Each of the high level power source lines 15 extends from the first end portion 15a in a direction away from the power source bus line 5.

Each of the second end portions 15b is connected to a connection line 6, so that the second end portions 15b adjacent to each other are connected to each other. Each of the second end portions 15b is an end portion on a side opposite to the first end portion 15a and is an end portion on a side far from the power source bus line 5, to which the first end portion 15a is connected. In other words, out of the both end portions of the high level power source line 15, the first end portion 15a is an end portion on a side close to a high level power source circuit 4, and the second end portion 15b is an end portion on a side far from the high level power source circuit 4.

The power source bus line 5 is connected to the high level power source circuit 4, and extends to be connected to the first end portion 15a of each of the high level power source lines 15. The power source bus line 5 is supplied with the high level power source voltage ELVDD from the high level power source circuit 4, and the high level power source voltage ELVDD is supplied to each of the high level power source lines 15 via this power source bus line 5.

A pixel circuit including the data line S(m), the scanning signal line G(n), the high level power source line 15, and the transistor T2 is formed in each of the pixels PIX. In addition, transistors and a capacitor are formed in the pixel circuit. A detailed configuration of the pixel circuit will be described later with reference to FIG. 3.

The passivation film 16 prevents a metal film in the transistor T2 or the like from being separated, and protects each transistor such as the transistor T2. The passivation film 16 is formed on the support body 11 or through another layer, and covers each transistor such as the transistor T2. The passivation film 16 is an inorganic insulating film made of silicon nitride, silicon oxide, or the like.

The interlayer insulating film 17 levels irregularities on the passivation film 16. The interlayer insulating film 17 is formed on the passivation film 16. The interlayer insulating film 17 is an organic insulating film made of photosensitive resin such as acrylic and polyimide.

The first electrode 21 and the second electrode 23 are a pair of electrodes. In the first embodiment, it is assumed that the first electrode 21 is a positive electrode and the second electrode 23 is a negative electrode.

The first electrode 21 is formed on the interlayer insulating film 17. The first electrode 21 injects (supplies) a positive hole (hole) into the light emitting portion 22, and the second electrode 23 injects an electron into the light emitting portion 22. The first electrode 21 and the second electrode 23 are disposed so as to face each other with the light emitting portion 22 interposed between the first electrode 21 and the second electrode 23.

The light emitting portion 22 is a light emitting element capable of emitting light at high luminance by low voltage DC driving. The light emitting portion 22 is formed between the first electrode 21 and the second electrode 23. Luminance at which light is emitted by the light emitting portion 22 is controlled by the pixel circuit, which is described later. Note that a configuration that is disposed in the pixel PIX and that includes the first electrode 21, the light emitting portion 22, and the second electrode 23 may be referred to as an organic EL element OLED.

The positive hole and the electron injected into the light emitting portion 22 are recombined in the light emitting portion 22 to form exciton. When the formed exciton is deactivated from an excited state to a ground state, light including red light, green light, blue light, or the like is radiated, and the radiated light is emitted from the light emitting portion 22 to the outside of the organic EL display device 1 through the second electrode 23 and the sealing layer 30.

The light emitting portion 22 is disposed in a region surrounded by the edge cover 25 in a case where a substrate surface is seen from a normal direction. Note that it is assumed that the light emitting portion 22 is a light emitting portion actually emitting light (contributing to image display) at the time of displaying an image and the light emitting portion 22 does not include a light emitting portion formed as a dummy and emitting no light (not contributing to image display).

The light emitting portion 22 includes light emitting portions 22a and 22b disposed at both ends. The light emitting portions 22a and 22b are light emitting portions that actually emit light at the time of displaying an image and are located at the both ends.

Out of the light emitting portions 22 disposed to be aligned along the high level power source line 15, the light emitting portion 22a is a light emitting portion located at an end on a side closest to the power source bus line 5, to which the high level power source line 15 is connected (namely, a side closest to the high level power source circuit 4). Out of the light emitting portions 22 disposed to be aligned along the high level power source line 15, the light emitting portion 22b is a light emitting portion located at an end on a side farthest from the power source bus line 5, to which the high level power source line 15 is connected (namely, a side farthest from the high level power source circuit 4).

Note that a vicinity of the first end portion 15a of the high level power source line 15 includes a region of the high level power source line 15 adjacent to the light emitting portion 22a. A vicinity of the second end portion 15b of the high level power source line 15 includes a region of the high level power source line 15 adjacent to the light emitting portion 22b.

In the first embodiment, the light emitting portion 22b has an area greater than an area of the light emitting portion 22a. Particularly in the first embodiment, each of the light emitting portions 22 has an area gradually increasing from the light emitting portion 22a toward the light emitting portion 22b.

The first electrode 21 is electrically connected to the drain electrode of the transistor T2 via a contact hole formed in the interlayer insulating film 17 and the passivation film 16. The first electrode 21 is a pixel electrode formed in an island shape for every pixel PIX and patterned to be aligned in a matrix.

Furthermore, the first electrode 21 is a reflective electrode. The first electrode 21 reflects light directed in a direction in which the first electrode 21 is disposed, out of the light emitted from the light emitting portion 22, and causes the light to pass through the light emitting portion 22, the second electrode 23, and the sealing layer 30 and to be emitted to the outside of the organic EL display device 1.

The first electrode 21 can include a conductive material having high reflectivity. The first electrode 21 can include silver or a silver alloy such as a silver-palladium-copper alloy, as an example.

Note that a conductive film made of, for example, ITO, Indium Zinc Oxide (IZO), or the like for improving adhesion properties between the first electrode 21 and the interlayer insulating film 17 may be formed between the first electrode 21 and the interlayer insulating film 17.

Furthermore, a conductive film made of, for example, ITO, IZO, or the like for protecting the first electrode 21 in a process of producing the organic EL display device 1 may be formed on the first electrode 21.

The edge cover 25 is formed in a grid pattern on the interlayer insulating film 17 so as to cover an edge of the first electrode 21.

The edge cover 25 is disposed between the pixels PIX adjacent to each other. In other words, the edge cover 25 serves as a partition between the pixels PIX adjacent to each other. The edge cover 25 prevents short-circuiting between the first electrode 21 and the second electrode 23 even in a case where an edge of the light emitting portion 22 is formed to be thin. The edge cover 25 is also provided to prevent an electrical field concentration on the edge of the first electrode 21. Accordingly, the light emitting portion 22 can be prevented from deteriorating. The edge cover 25 can include photosensitive resin such as acrylic and polyimide.

The light emitting portion 22 is formed in a region surrounded by the edge cover 25. The light emitting portion 22 contacts an inner wall of the edge cover 25. The edge cover 25 functions as a bank that holds back a liquid material to be the light emitting portion 22 in a case where the light emitting portion 22 is formed by an ink-jet method.

The light emitting portion 22 can be formed by vapor deposition, an ink-jet method, or the like. The light emitting portion 22 has a configuration in which, for example, a hole injecting layer, a hole transport layer, a light emitting layer, an electron transport layer, and an electron injecting layer are layered in this order from the first electrode 21 side. Note that one layer may have a plurality of functions. For example, a hole injection-cum-transport layer having functions of the hole injecting layer and the hole transport layer may be provided instead of the hole injecting layer and the hole transport layer. An electron injection-cum-transport layer having functions of the electron injecting layer and the electron transport layer may be provided instead of the electron injecting layer and the electron transport layer. A carrier blocking layer may be appropriately provided between the layers.

The second electrode 23 is formed on the entire surface of the display region including a top of the light emitting portion 22 and a top of the edge cover 25. In other words, the second electrode 23 is continuously formed across the pixels PIX. Note that the second electrode 23 may be patterned in an island shape for every pixel PIX. The second electrode 23 includes a transparent conductive material. The second electrode 23 can include ITO, IZO, or the like, as an example.

The sealing layer 30 is formed on the second electrode 23 and above the edge cover 25. The sealing layer 30 seals the entire surface of the display region and the frame region. The sealing layer 30 performs Thin Film Encapsulation (TFE) on the light emitting portion 22 to prevent the light emitting portion 22 from deteriorating by moisture or oxygen entering from the outside.

The sealing layer 30 can have a three-layered structure in which an inorganic layer, an organic layer, and an inorganic layer are layered in this order, as an example. Examples of a material for the organic layer may include an organic insulating material (resin material) such as polysiloxane, silicon oxycarbide (SiOC), acrylate, polyurea, parylene, polyimide, and polyamide. Examples of a material for the inorganic layer includes an inorganic insulating material such as silicon nitride, silicon oxide, silicon oxynitride, and Al₂O₃. Note that a structure of the sealing layer 30 is not limited to the three-layered structure described above.

The first embodiment gives the description on the assumption that the first electrode 21 is a positive electrode (pattern electrode, pixel electrode) and the second electrode 23 is a negative electrode (common electrode). However, the first electrode 21 may be a negative electrode and the second electrode 23 may be a positive electrode. In this case, it should be noted that an order of the layers constituting the light emitting portion 22 is reversed.

Furthermore, the first embodiment gives the description on the assumption that the organic EL display device 1 is a top-emitting type that emits light that has been emitted from the light emitting portion 22 to the outside from the sealing layer 30. However, in a case where the organic EL display device 1 is a bottom-emitting type that emits light that has been emitted from the light emitting portion 22 to the outside from a back surface side of the support body 11, the second electrode 23 has the same configuration as that of the first electrode 21 and the first electrode 21 is formed of a transparent electrode or a semitransparent electrode made of a transparent electrode material, which is transparent or semitransparent.

### Pixel Circuit

A configuration of a pixel circuit 52 of the organic EL display device 1 is described with reference to FIGS. 1 and 3.

FIG. 3 is a diagram illustrating a configuration of the pixel circuit 52 of the organic EL display device 1 according to the first embodiment of the disclosure. FIG. 3 illustrates a configuration of the pixel circuit 52 corresponding to an m-th column and an n-th row. Note that the configuration of the pixel circuit 52 described herein is an example, and another known configuration can be adopted.

As described above, the plurality of data lines S(m) and the plurality of scanning signal lines G(n) orthogonal to the plurality of data lines S(m) are arranged in the display region of the organic EL display device 1. A plurality of light emission control lines EM(n) are also arranged so as to correspond to the plurality of scanning signal lines G(n) on a one-to-one basis in the display region. Furthermore, the pixel circuits 52 are provided so as to correspond to intersections of the plurality of data lines S(m) and the plurality of scanning signal lines G(n) in the display region. The pixel circuits 52 are provided in such a manner, so that the plurality of pixels PIX are formed in a matrix in the display region.

Power source lines common to the pixel circuits 52 are formed in the display region. More specifically, the high level power source line 15 that supplies the high level power source voltage ELVDD for driving an organic EL element, a power source line (hereinafter, referred to as a “low level power source line”) that supplies a low level power source voltage ELVSS for driving the organic EL element, and a power source line (hereinafter, referred to as an “initialization power source line”) that supplies an initialization voltage Vini are formed. The high level power source voltage ELVDD is supplied from the high level power source circuit 4. The low level power source voltage ELVSS and the initialization voltage Vini are supplied from power source circuits, which are not illustrated.

The pixel circuit 52 is supplied with the high level power source voltage ELVDD from the high level power source line 15 and controls a signal given to the light emitting portion 22 (see FIGS. 1 and 2) included in the organic EL element OLED.

The pixel circuit 52 includes one organic EL element OLED, six transistors T1 to T6, and one capacitor C1. The transistors T1 to T6 are p-channel transistors. The capacitor C1 is a capacitative element including two electrodes (first electrode and second electrode). The transistor T1 is a drive transistor. The transistor T2 is a writing control transistor. The transistor T3 is a power source supply control transistor. The transistor T4 is a light emission control transistor. The transistor T5 is a threshold voltage compensation transistor. The transistor T6 is an initialization transistor.

The high level power source circuit 4 is connected to the capacitor C1 and the transistor T3 via the power source bus line 5 and the high level power source circuit 4.

The organic EL element OLED is considered to be a diode including the first electrode 21 (see FIG. 2) as an anode, and the second electrode 23 (see FIG. 2) as a cathode. A voltage according to a display image is applied to the first electrode 21. The second electrode 23 is supplied with the low level power source voltage ELVSS being a constant voltage different from the high level power source voltage ELVDD.

The anode (first electrode 21) of the organic EL element OLED is connected to the transistor T4. The transistor T4 is connected to the transistor TS. The transistor TS is connected to the capacitor C1.

The data line S(m) is connected to the transistor T2. The transistor T2 is connected to the transistor T3. The transistor T3 is connected to the high level power source line 15 and the capacitor C1.

The capacitor C1 and the transistors T1 to TS constitute a voltage conversion circuit 53. The voltage conversion circuit 53 is connected to the high level power source line 15 and the anode (first electrode 21) of the organic EL element OLED. The voltage conversion circuit 53 converts the high level power source voltage ELVDD supplied from the high level power source line 15 to a voltage according to a gray scale level corresponding to an displayed image (display image), and the converted voltage corresponding to the display image is supplied to the anode (first electrode 21) of the organic EL element OLED.

In a case where a scanning signal is input from a scanning signal line G(n−1), the transistor T6 including the gate electrode connected to the scanning signal line G(n−1) is switched from OFF to ON, and the capacitor C1 is initialized by the initialization voltage Vini supplied to the transistor T6. Then, the transistor T6 is switched from ON to OFF. Accordingly, the high level power source voltage ELVDD is supplied from the high level power source circuit 4 to the capacitor C1 via the high level power source line 15, and an electric charge is accumulated in the capacitor C1.

In a case where a light emission control signal is input from the light emission control line EM(n), the transistors T4 and T3 each including the gate electrode connected to the light emission control line EM(n) are switched from OFF to ON.

Next, in a case where a scanning signal is input from the scanning signal line G(n), the transistors T5 and T2 each including the gate electrode connected to the scanning signal line G(n) are then switched from OFF to ON. Accordingly, a predetermined amount of the electric charges accumulated in the capacitor C1 is extracted to the data line S(m) via the transistors T3 and T2, and the rest of the electric charges accumulated in the capacitor C1 causes the voltage according to the display image, which needs to be output to the organic EL element OLED, to be supplied to the organic EL element OLED via the transistors T5 and T4. Accordingly, the voltage according to the display image supplied to the anode (first electrode 21) and the low level power source voltage ELVSS being a constant voltage supplied to the cathode (second electrode 23) in the organic EL element OLED cause the light emitting portion 22 in the organic EL element OLED to emit light.

### Advantageous Effects

In this way, the organic EL display device 1 includes each of the high level power source lines 15 connected to the high level power source circuit 4 and the pixel circuit 52 disposed in each of the pixels PIX. In each of the pixels PIX, the pixel circuit 52 is supplied with the high level power source voltage ELVDD supplied from the high level power source line 15 and causes the light emitting portion 22 included in the organic EL element OLED to emit light at predetermined luminance according to a display image.

Here, out of the both end portions of each of the high level power source lines 15, the first end portion 15a is an end portion connected to the power source bus line 5 on a side close to the power source bus line 5, and the second end portion 15b on the opposite side is an end portion on a side far from the power source bus line 5. Each of the high level power source lines 15 is supplied with the high level power source voltage ELVDD being a constant voltage from the high level power source circuit 4 via the power source bus line 5.

Thus, in a case where, out of the both end portions of each of the high level power source lines 15, the first end portion 15a on the side supplied with the high level power source voltage ELVDD has a resistance greater than that of the second end portion 15b on the opposite side, a voltage value of the high level power source voltage ELVDD being a constant voltage can easily vary for every high level power source line 15.

As illustrated in FIG. 1, in the organic EL display device 1 according to the first embodiment, out of the both end portions of each of the high level power source lines 15, a resistance value per unit length near the first end portion 15a on the side supplied with the high level power source voltage ELVDD is smaller than a resistance value per the unit length near the second end portion 15b on the opposite side.

Specifically, in a case where the display region of the organic EL display device 1 is seen from the normal direction, each of the high level power source lines 15 has an area per unit length near the first end portion 15a greater than an area per the unit length near the second end portion 15b.

More specifically, in a case where the display region of the organic EL display device 1 is seen from the normal direction, each of the high level power source lines 15 has a width Wva near the first end portion 15a thicker than an width Wvb near the second end portion 15b.

Thus, the high level power source voltage ELVDD being a constant voltage can be stably supplied from the high level power source circuit 4 to each of the high level power source lines 15 via the first end portion 15a. Accordingly, the voltage conversion circuit 53 can accurately set a gradation voltage from the supplied high level power source voltage ELVDD and supply the gradation voltage to the first electrode 21. As a result, variations in luminance of the pixels PIX can be reduced in the whole display region.

Particularly, in the first embodiment, each of the high level power source lines 15 has a width Wv gradually increased from the second end portion 15b side toward the first end portion 15a side. Accordingly, a resistance value near the second end portion 15b in which a resistance value is increased by wiring resistance can be sufficiently reduced in each of the high level power source lines 15. Thus, the high level power source voltage ELVDD can be stably supplied from the high level power source circuit 4 from the first end portion 15a to the second end portion 15b in each of the high level power source lines 15.

Here, each of the high level power source lines 15 is likely to have a greater resistance value in the vicinity of the second end portion 15b, in which a resistance value is added up by wiring resistance than the vicinity of the first end portion 15a. A greater resistance value near the second end portion 15b increases a voltage supplied from the voltage conversion circuit 53 to the first electrode 21 included in the pixel PIX near the second end portion 15b more than a voltage according to a display image, and thus an amount of light per unit area of the light emitting portion 22b near the second end portion 15b is likely to be reduced more than an amount of light per unit area of the light emitting portion 22a near the first end portion 15a.

However, in the first embodiment, each of the high level power source lines 15 has a width near the first end portion 15a thicker than a normal width, so that a resistance value of the second end portion 15b is also smaller than that of a normal high level power source line.

For example, a 5.5-inch, 1440 (pix)×2560 (pix) panel for a Pen Tile organic EL display device is given as an example. It is assumed that a wiring width of a high level power source line is 4 μm, and a length per one pixel in a direction orthogonal to the wiring width of the high level power source line is 48 μm.

A high level power source line in an organic EL display device in the related art has a constant width of 4 μm from one end portion on a side connected to a power source bus line to the other end portion on a side connected to a connection line on an opposite side. Thus, an area per one pixel of the high level power source line in the organic EL display device is 192 μm². Then, in the high level power source line, a voltage drop of 0.021 mV/pix occurs in the other end portion with respect to the one end portion. Thus, a resistance value is added up from the one end portion and a voltage drop of 53.76 mV occurs in the other end portion of the high level power source line.

For example, in a case where a voltage drop of 1 mV occurs in a panel of 400 cd/m², luminance of 1 cd/m² decreases. In other words, in the organic EL display device in the related art, luminance of approximately 53.75 cd/m² of a pixel near the connection line on the opposite side decreases in comparison with luminance of a pixel near the power source bus line.

On the other hand, in the organic EL display device 1 according to the first embodiment, it is assumed that the high level power source line 15 has a width of the first end portion 15a on the side connected to the power source bus line 5 greater than a width of that in the device in the related art. It is assumed that a width of the first end portion 15a is approximately 6 μm, as an example. It is also assumed that the high level power source line 15 has the same width of the second end portion 15b on the side connected to the connection line 6 on the opposite side as a width of that in the device in the related art. It is assumed that a width of the second end portion 15b is approximately 4 μm, as an example. Accordingly, an area of the wiring of the high level power source line 15 is 1.25 times an area of the wiring of the high level power source line in the related art, as described above. In other words, in the organic EL display device 1 according to the first embodiment, a resistance value of the high level power source line 15 is 0.8 times that in the organic EL display device in the related art. Thus, in the organic EL display device 1 according to the first embodiment, a decrease in luminance of the pixel PIX near the connection line 6 on the opposite side with respect to luminance of the pixel PIX near the power source bus line 5 can be reduced to approximately 43 cd/m².

Furthermore, in the first embodiment, out of the light emitting portions 22 disposed to be aligned along each of the high level power source lines 15, the light emitting portion 22b near the second end portion 15b has an area greater than an area of the light emitting portion 22a near the first end portion 15a. Thus, a difference in luminance between the whole light emitting portion 22b near the second end portion 15b and the whole light emitting portion 22a near the first end portion 15a can be reduced. As a result, variations in luminance of the pixels PIX can be reduced in the whole display region.

In the organic EL display device 1, an area gradually increases from the light emitting portion 22a toward the light emitting portion 22b, so that variations in luminance of the pixels PIX can be reduced in the whole display region of the organic EL display device 1.

In the first embodiment, the width Wv of the high level power source line 15 is set to be gradually thinner from the width Wva toward the width Wvb. Thus, a space for gradually increasing an area of the light emitting portion 22 from the light emitting portion 22a to the light emitting portion 22b can be secured along the high level power source line 15.

It is assumed that a width of the edge cover 25 extending along the high level power source line 15 is a width We. It is also assumed that, out of the width We, a width between the light emitting portions 22a adjacent to each other is a width Wea, and a width between the light emitting portions 22b adjacent to each other is a width Web. In the first embodiment, a width gradually increases from the width Wea toward the width Web for every light emitting portion 22. Accordingly, an area of the light emitting portion 22 is configured to gradually increase from the light emitting portion 22a to the light emitting portion 22b.

Note that each of the high level power source lines 15 may have a resistance value per unit length decreased from the first end portion 15a side toward the second end portion 15b side in at least a part of a section ranging from the first end portion 15a to the second end portion 15b. Specifically, each of the high level power source lines 15 may have an area per unit length in a section on the first end portion 15a side greater than an area per the unit length in a section on the second end portion 15b side in at least a part of a section ranging from the first end portion 15a to the second end portion 15b. More specifically, in a case where the display region of the organic EL display device 1 is seen from the normal direction, each of the high level power source lines 15 may have a width in the section on the first end portion 15a side thicker than a width in the section on the second end portion 15b side in at least a part of a section ranging from the first end portion 15a to the second end portion 15b.

Also in this way, a resistance value on the first end portion 15a side being the side supplied with the high level power source voltage ELVDD can be reduced in each of the high level power source lines 15, so that the pixel circuit 52 can cause the light emitting portion 22 to stably emit light at luminance according to a display image.

Each of the high level power source lines 15 may particularly have a width gradually increased from the first end portion 15a side toward the second end portion 15b side in at least a part of a section ranging from the first end portion 15a to the second end portion 15b. Accordingly, a resistance value near the second end portion 15b in which a resistance value is increased by wiring resistance can be sufficiently reduced in each of the high level power source lines 15 including the at least a part of a section. Also in this way, the high level power source voltage ELVDD can be stably supplied from the high level power source circuit 4 from the first end portion 15a to the second end portion 15b in each of the high level power source lines 15.

Furthermore, out of the light emitting portions 22 disposed to be aligned along each of the high level power source lines 15, an area of the light emitting portion 22 included in the pixel PIX on the second end portion 15b side of the pixels PIX aligned to be adjacent to at least a part of a section ranging from the first end portion 15a to the second end portion 15b in the high level power source line 15 may be greater than an area of the light emitting portion 22 included in the pixel PIX on the first end portion side 15a. Also in this way, a difference in luminance between the light emitting portion 22 included in the pixel PIX on the second end portion 15b side of the pixels PIX aligned to be adjacent to the at least a part of a section and the light emitting portion 22 included in the pixel PIX on the first end portion 15a side can be reduced. Thus, variations in luminance of the pixels PIX can be reduced in the whole display region. The light emitting portions 22 included in the pixels PIX aligned to be adjacent to the at least a part of a section may have an area gradually increased from the light emitting portion 22 included in the pixel PIX on the first end portion 15a side toward the light emitting portion 22 included in the pixel PIX on the second end portion 15b side. Also in this way, variations in luminance of the pixels PIX can be reduced in the whole display region of the organic EL display device 1.

Note that even in a case where a display device other than the organic EL display device 1, for example, an inorganic EL display device or a liquid crystal display device is used as the display device according to the first embodiment, the high level power source line 15 may be a wire for supplying voltage or current from a power source circuit to a pixel electrode disposed in every pixel.

In a case where a display device is configured by using a liquid crystal display device instead of an organic EL display device, an electro-optic element is a liquid crystal layer sandwiched between a pixel electrode and a counter electrode. The liquid crystal layer sandwiched between the pixel electrode and the counter electrode has a transmittance, at which light from a backlight is caused to pass, and which is controlled by a potential difference between the pixel electrode and the counter electrode.

### Second Embodiment

A second embodiment of the disclosure will be described below. For the convenience of description, components having the same function as the components stated in the first embodiment are appended with the same reference signs, and the description thereof is omitted.

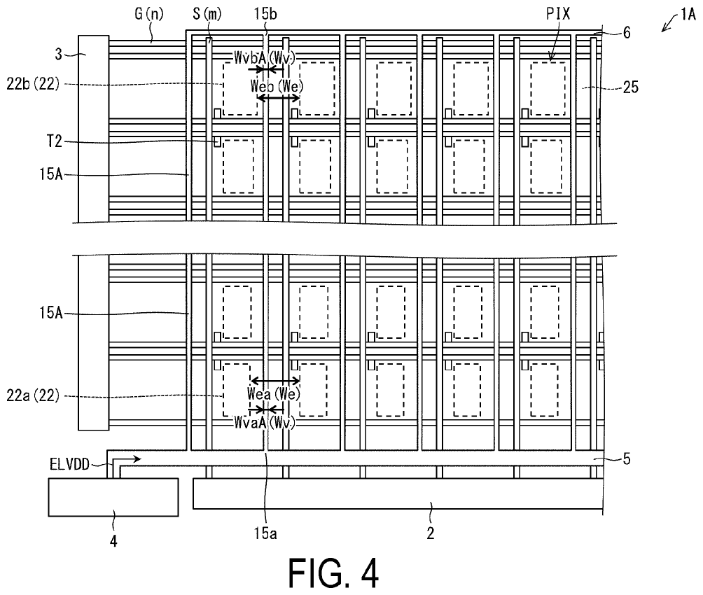

FIG. 4 is a plan view illustrating a configuration of an organic EL display device 1A according to the second embodiment of the disclosure. The organic EL display device (display device) 1A includes a high level power source line 15A instead of the high level power source line 15 of the organic EL display device 1. The other configuration of the organic EL display device 1A is the same as that of the organic EL display device 1.

For a width Wv of the high level power source line 15A, a width WvaA near the first end portion 15a and a width WvbA near the second end portion 15b are the same. In other words, the high level power source line 15A has the width Wv constant from the vicinity of the first end portion 15a to the vicinity of the second end portion 15b. Furthermore, the width Wv is constant from the first end portion 15a to the second end portion 15b.

Out of the light emitting portions 22 disposed to be aligned along each of the high level power source lines 15A, an area of the light emitting portion 22b near the second end portion 15b is greater than an area of the light emitting portion 22a near the first end portion 15a.

Furthermore, also in the organic EL display device 1A, an area gradually increases from the light emitting portion 22a toward the light emitting portion 22b similarly to the organic EL display device 1.

Also in such an organic EL display device 1A, variations in luminance of the pixels PIX can be reduced in the whole display region.

### Third Embodiment

A third embodiment of the disclosure will be described below. For the convenience of description, components having the same function as the components stated in the first and second embodiments are appended with the same reference signs, and the description thereof is omitted.

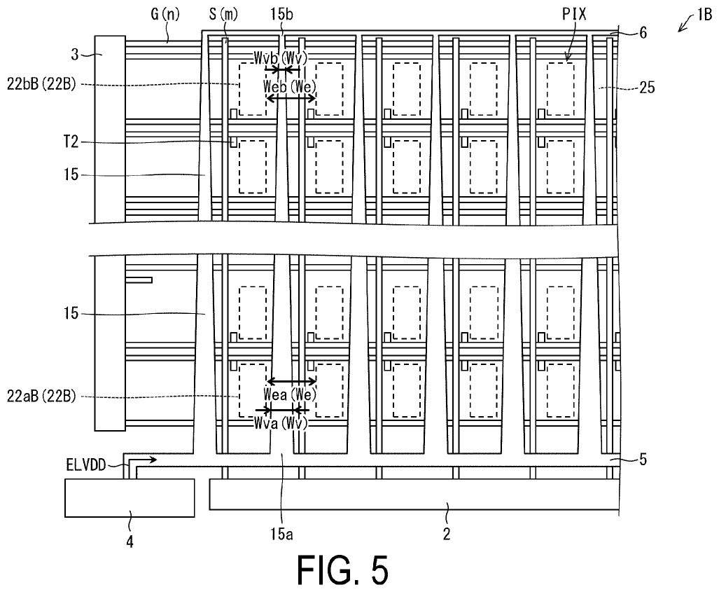

FIG. 5 is a plan view illustrating a configuration of an organic EL display device 1B according to the third embodiment of the disclosure.

The organic EL display device (display device) 1B includes a light emitting portion 22B instead of the light emitting portion 22 of the organic EL display device 1. The other configuration of the organic EL display device 1B is the same as that of the organic EL display device 1.

Out of the light emitting portions 22B disposed to be aligned along the high level power source line 15, an area of a light emitting portion 22aB near the first end portion 15a of the high level power source line 15 is the same as an area of a light emitting portion 22bB near the second end portion 15b of the high level power source line 15. In other words, the light emitting portions 22B have the same area from the light emitting portion 22aB toward the light emitting portion 22bB.

A width We of the edge cover 25 is also constant from a width Wea between the light emitting portions 22aB adjacent to each other toward a width Web between the light emitting portions 22bB adjacent to each other.

Each of the high level power source lines 15 has a width near the first end portion 15a greater than a width near the second end portion 15b. Furthermore, also in the organic EL display device 1B, each of the high level power source lines 15 has a width Wv gradually increased from a width Wvb near the second end portion 15b toward a width Wva near the first end portion 15a similarly to the organic EL display device 1 (see FIG. 1).

Also in such an organic EL display device 1B, variations in luminance of each of the pixels PIX can be reduced in the whole display region.

### Fourth Embodiment

A fourth embodiment of the disclosure will be described below. For the convenience of description, components having the same function as the components stated in the first to third embodiments are appended with the same reference signs, and the description thereof is omitted.

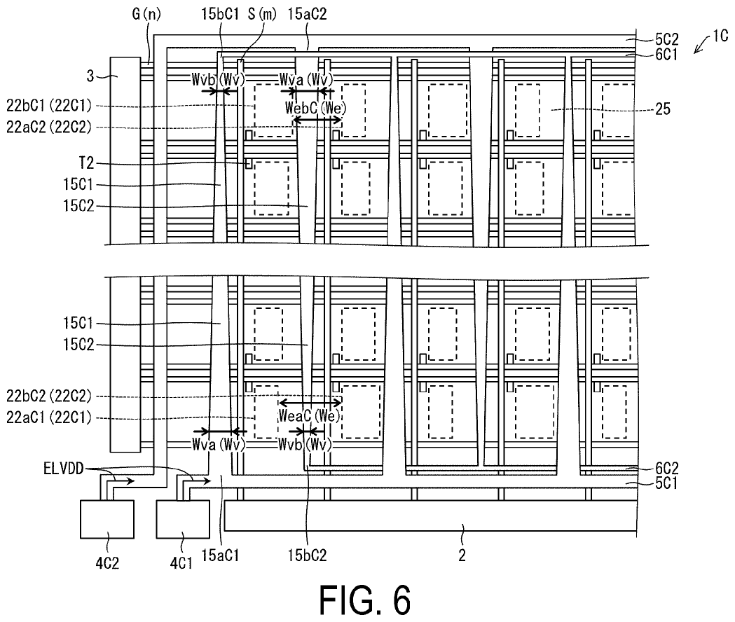

FIG. 6 is a plan view illustrating a configuration of an organic EL display device 1C according to the fourth embodiment of the disclosure.

The organic EL display device (display device) 1C includes high level power source lines 15C1 and 15C2, power source bus lines 5C1 and 5C2, high level power source circuits 4C1 and 4C2, and light emitting portions 22C1 and 22C2 instead of the high level power source lines 15, the power source bus line 5, the high level power source circuit 4, and the light emitting portions 22 of the organic EL display device 1, respectively. The other configuration of the organic EL display device 1C is the same as that of the organic EL display device 1.

The high level power source lines 15C1 and the high level power source lines 15C2 are disposed to be aligned alternately.

Each high level power source line 15C1 is a high level power source line in an odd column, and each high level power source line 15C2 is a high level power source line in an even column.

Each of the high level power source lines 15C1 includes a first end portion 15aC1 and a second end portion 15bC1 being both end portions. Each first end portion 15aC1 is connected to the power source bus line 5C1, so that the first end portions 15aC1 are connected to each other. In other words, each of the first end portions 15aC1 is an end portion on a side close to the power source bus line 5C1. Each of the high level power source lines 15C1 extends from the first end portion 15aC1 in a direction away from the power source bus line 5C1.

Each second end portion 15bC1 is connected to a connection line 6C1, so that the second end portions 15bC1 are connected to each other. Each second end portion 15bC1 is an end portion on a side opposite to the first end portion 15aC1 and is an end portion on a side far from the power source bus line 5C1 to which the first end portion 15aC1 is connected.

The power source bus line 5C1 is connected to the high level power source circuit 4C1 and extends to be connected to the first end portion 15aC1 of each of the high level power source lines 15C1. The power source bus line 5C1 is supplied with the high level power source voltage ELVDD from the high level power source circuit 4C1, and the high level power source voltage ELVDD is supplied to each of the high level power source lines 15C1 via this power source bus line 5C1.

Each of the high level power source lines 15C1 has a width Wv gradually increased from a width Wvb near the second end portion 15bC1 toward a width Wva near the first end portion 15aC1. Furthermore, each of the high level power source lines 15C1 has a width gradually increased from the second end portion 15bC1 toward the first end portion 15aC1.

Each of the high level power source lines 15C2 includes a first end portion 15aC2 and a second end portion 15bC2 being both end portions. Each first end portion 15aC2 is connected to the power source bus line 5C2, so that the first end portions 15aC2 are connected to each other. In other words, each of the first end portions 15aC2 is an end portion on a side close to the power source bus line 5C2. Each of the high level power source lines 15C2 extends from the first end portion 15aC2 in a direction away from the power source bus line 5C2.

Each second end portion 15bC2 is connected to a connection line 6C2, so that the second end portions 15bC2 are connected to each other. Each of the second end portions 15bC2 is an end portion on a side opposite to the first end portion 15aC2 and is an end portion on a side far from the power source bus line 5C2 to which the first end portion 15aC2 is connected.

The power source bus line 5C2 is connected to the high level power source circuit 4C2 and extends to be connected to the first end portion 15aC2 of each of the high level power source lines 15C2. The power source bus line 5C2 is supplied with the high level power source voltage ELVDD from the high level power source circuit 4C2, and the high level power source voltage ELVDD is supplied to each of the high level power source lines 15C2 via this power source bus line 5C2.

Each of the high level power source lines 15C2 has a width Wv gradually increased from a width Wvb near the second end portion 15bC2 toward a width Wva near the first end portion 15aC2. Furthermore, each of the high level power source lines 15C2 has a width gradually increased from the second end portion 15bC2 toward the first end portion 15aC2.

The power source bus line 5C1 and the power source bus line 5C2 face each other with the pixels PIX arranged in a matrix interposed between the power source bus line 5C1 and the power source bus line 5C2.

The high level power source line 15C1 and the high level power source line 15C2 adjacent to each other are formed in a comb-like shape in which positions of the first end portions 15aC1 and 15aC2 and the second end portions 15bC1 and 15bC2 are reversed. In other words, the first end portion 15aC1 of the high level power source line 15C1 and the second end portion 15bC2 of the high level power source line 15C2 are adjacent to each other while the second end portion 15bC1 of the high level power source line 15C1 and the first end portion 15aC2 of the high level power source line 15C2 are adjacent to each other.

Accordingly, the high level power source voltage ELVDD being a constant voltage in which variations in a voltage value are reduced is supplied to each of the pixels PIX from both directions of the pixels PIX arranged in a matrix.

In this way, the high level power source voltage ELVDD can be supplied from the plurality of high level power source circuits 4C1 and 4C2 to the respective high level power source lines 15C1 and 15C2. Accordingly, the high level power source voltage ELVDD can be stably supplied to each of the high level power source lines 15C1 and 15C2. Each of the high level power source circuits 4C1 and 4C2 can be reduced in size in comparison with the case where the high level power source voltage ELVDD is supplied from one power source circuit to all high level power source lines. Thus, a degree of flexibility in positions at which the high level power source circuits 4C1 and 4C2 are disposed can be increased. In other words, a degree of flexibility in circuit design can be increased.

The light emitting portions 22C1 supplied with the high level power source voltage ELVDD from the high level power source line 15C1 are disposed to be aligned along the high level power source line 15C1. Out of the light emitting portions 22C1, an area of the light emitting portion 22bC1 near the second end portion 15bC1 of the high level power source line 15C1 is greater than an area of the light emitting portion 22aC1 near the first end portion 15aC1. Furthermore, an area gradually increases from the light emitting portion 22aC1 toward the light emitting portion 22bC1.

The light emitting portions 22C2 supplied with the high level power source voltage ELVDD from the high level power source line 15C2 are disposed to be aligned along the high level power source line 15C2. Out of the light emitting portions 22C2, an area of the light emitting portion 22bC2 near the second end portion 15bC2 of the high level power source line 15C2 is greater than an area of the light emitting portion 22aC2 near the first end portion 15aC2. Furthermore, an area gradually increases from the light emitting portion 22aC2 toward the light emitting portion 22bC2.

Thus, variations in luminance of each of the pixels PIX can be reduced in the whole display region of the organic EL display device 1C.

A width We of the edge cover 25 is constant from a width WeaC between the light emitting portion 22aC1 and the light emitting portion 22bC2 adjacent to each other toward a width WebC between the light emitting portion 22bC1 and the light emitting portion 22aC2 adjacent to each other.

### Fifth Embodiment

A fifth embodiment of the disclosure will be described below. For the convenience of description, components having the same function as the components stated in the first to fourth embodiments are appended with the same reference signs, and the description thereof is omitted.

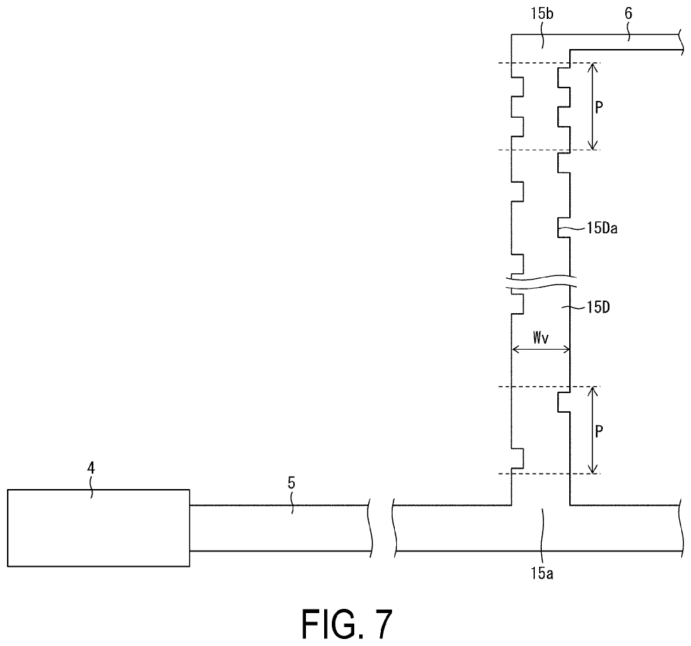

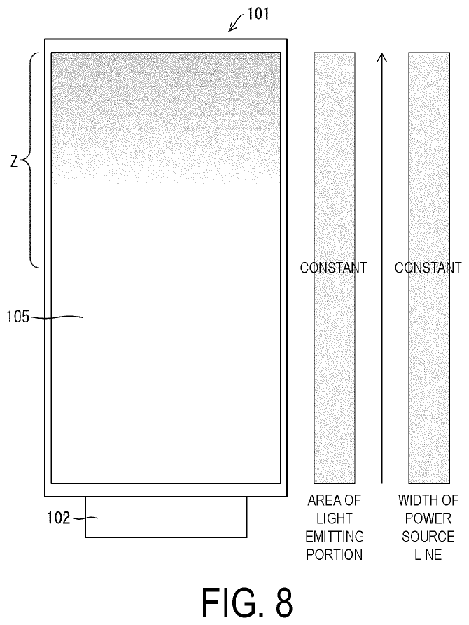

FIG. 7 is a plan view illustrating a configuration of a high level power source line 15D of an organic EL display device according to the fifth embodiment of the disclosure.

The organic EL display device 1 (see FIG. 1) may include the high level power source line 15D illustrated in FIG. 7 instead of the high level power source line 15. Note that FIG. 7 illustrates only one high level power source line 15D for the sake of simplification, but it is assumed that m high level power source lines 15D are disposed to be aligned in parallel, similarly to the high level power source lines 15.

The high level power source line 15D has a width Wv constant, but a plurality of notches 15Da for adjusting a resistance value in at least a part of a section ranging from the first end portion 15a to the second end portion 15b are formed.

An area of the plurality of notches 15Da included per unit length P near the first end portion 15a of the high level power source line 15D is smaller than an area of the plurality of notches 15Da included per the unit length P near the second end portion 15b of the high level power source line 15D. FIG. 7 illustrates an example in which areas of the notches 15Da is the same in a case where a substrate surface is seen from the normal direction and the number of the notches 15Da included per the unit length P near the first end portion 15a of the high level power source line 15D is smaller than the number of the notches 15Da included per the unit length P near the second end portion 15b of the high level power source line 15D.

Accordingly, each of the high level power source lines 15D has a configuration in which an area per the unit length P near the first end portion 15a is greater than an area per the unit length P near the second end portion 15b. Thus, the high level power source voltage ELVDD can be stably supplied from the high level power source circuit 4 to each of the high level power source lines 15D.

Note that each of the high level power source lines 15D may have an area of the notches 15Da per the unit length P in a section on the first end portion 15a side smaller than an area of the notches 15Da per the unit length P in a section on the second end portion 15b side in at least a part of a section ranging from the first end portion 15a to the second end portion 15b.

### Supplement

A display device according to a first aspect of the disclosure is a display device including a display region including pixels disposed in a row direction and a column direction, each of the pixels including a first electrode and a second electrode facing each other with an electro-optic element interposed between the first electrode and the second electrode, the display device including: a power source circuit serving as a supply source of a voltage supplied to the first electrode; power source lines connected to the power source circuit to be supplied with a constant voltage from the power source circuit; and pixel circuits respectively disposed in the pixels, each of the pixel circuits including the electro-optic element, the first electrode, and the second electrode, each of the pixel circuits being configured to be supplied with the constant voltage from at least one of the power source lines and to control a signal to be given to the electro-optic element. Each of the power source lines extends along the pixels aligned in the row direction or the column direction, and includes a first end portion being on a first end portion side to be supplied with the constant voltage from the power source circuit and a second end portion being on a second end portion side opposite to the first end portion, and a resistance value per unit length in each of the power source lines is reduced from the first end portion side to the second end portion side in at least a part of a section ranging from the first end portion to the second end portion.

According to the configuration above, out of the first end portion being an end portion on the side to be supplied with the constant voltage from the power source circuit and the second end portion being an end portion on the side opposite to the first end portion, each of the power source lines has a resistance value per unit length near the first end portion smaller than a resistance value per the unit length near the second end portion. Thus, the constant voltage can be stably supplied from the power source circuit to each of the power source lines via the first end portion. Accordingly, the gradation voltage can be accurately set and supplied to the first electrode. As a result, variations in luminance of the pixels can be reduced in the whole display region.

In a display device according to a second aspect of the disclosure in the above first aspect, each of the power source lines may preferably have a resistance value gradually reduced from the second end portion toward the first end portion. Accordingly, the resistance value near the second end portion can be sufficiently reduced. Thus, the constant voltage can be stably supplied from the power source circuit from the first end portion to the second end portion in each of the power source lines.

In a display device according to a third aspect of the disclosure in the above first or second aspect, in a case where the display region is seen from a normal direction, in each of the power source lines, an area per the unit length in a section on the first end portion side in at least the part of the section may be preferably greater than an area per the unit length in a section on the second end portion side.

In a display device according to a fourth aspect of the disclosure in the above first to third aspects, in a case where the display region is seen from a normal direction, in each of the power source lines, a width in a section on the first end portion side in at least the part of the section may be preferably greater than a width in a section on the second end portion side.

In a display device according to a fifth aspect of the disclosure in the above first to fourth aspects, a notch may be preferably arranged to adjust the resistance value of each of the power source lines in at least the part of the section.

In a display device according to a sixth aspect of the disclosure in the above fifth aspect, in a case where the display region is seen from a normal direction, an area of the notch included in the unit length in a section on the first end portion side, in at least the part of the section may be preferably smaller than an area of the notch included in the unit length in a section on the second end portion side.

Accordingly, a resistance value near the first end portion can be set to be smaller than a resistance value near the second end portion.

In a display device according to a seventh aspect of the disclosure in the above first to sixth aspects, the power source lines may be preferably formed in a comb-like shape in which positions of first end portions and second end portions of the power source lines adjacent to each other are reversed. According to the configuration above, the constant voltage can be supplied from a plurality of power source circuits to each of the power source lines. Accordingly, the constant voltage can be more stably supplied to each of the power source lines.

In a display device according to an eighth aspect of the disclosure in the above first to seventh aspects, out of the pixels aligned to be adjacent to at least the part of the section in each of the power source lines, an area of the electro-optic element included in a pixel of the pixels on the second end portion side may be preferably greater than an area of the electro-optic element included in a pixel of the pixels on the first end portion side.

A display device according to a ninth aspect of the disclosure is a display device including a display region including pixels disposed in a row direction and a column direction, each of the pixels including a first electrode and a second electrode facing each other with an electro-optic element interposed between the first electrode and the second electrode, the display device including: a power source circuit serving as a supply source of a voltage supplied to the first electrode; power source lines connected to the power source circuit to be supplied with a constant voltage from the power source circuit; and pixel circuits respectively disposed in the pixels, each of the pixel circuits including the electro-optic element, the first electrode, and the second electrode, each of the pixel circuits being configured to be supplied with the constant voltage from at least one of the power source lines and to control a signal to be given to the electro-optic element. Each of the power source lines extends along the pixels aligned in the row direction or the column direction, and includes a first end portion being on a first end portion side to be supplied with the constant voltage from the power source circuit and a second end portion being on a second end portion side opposite to the first end portion, and out of the pixels aligned to be adjacent to at least a part of a section ranging from the first end portion to the second end portion in each of the power source lines, an area of the electro-optic element included in a pixel of the pixels on the second end portion side is greater than an area of the electro-optic element included in a pixel of the pixels on the first end portion side.

Here, each of the power source lines is likely to have a greater resistance value in the vicinity of the second end portion in which a resistance value is added up than the vicinity of the first end portion. A greater resistance value near the second end portion increases the gradation voltage supplied to the first electrode included in the pixel near the second end portion, and thus luminance per unit area of a light emitting portion near the second end portion is likely to be reduced more than luminance per unit area of a light emitting portion near the first end portion. According to the configuration above, however, out of the pixels aligned to be adjacent to the at least a part of the section, an area of the electro-optic element on the second end portion side is greater than an area of the electro-optic element on the first end portion side. Thus, a difference in luminance between the whole electro-optic element on the second end portion side and the whole electro-optic element on the first end portion side can be reduced. As a result, variations in luminance of the pixels can be reduced in the whole display region.

In a display device according to a tenth aspect of the disclosure in the above eighth or ninth aspects, an area may preferably gradually increase from the electro-optic element included in the pixel of the pixels on the first end portion side toward the electro-optic element included in the pixel of the pixels on the second end portion side. According to the configuration above, variations in luminance of the pixels can be reduced in the whole display region.

In a display device according to an eleventh aspect of the disclosure in the above first to tenth aspects, in the power source lines, first end portions adjacent to each other may be preferably connected to each other.

In a display device according to a twelfth aspect of the disclosure in the above first to eleventh aspects, in the power source lines, second end portions adjacent to each other may be preferably connected to each other.

In a display device according to a thirteenth aspect of the disclosure in the above first to twelfth aspects, preferably, the first electrode may be arranged in an island shape for each pixel, the second electrode may be continuously disposed across the pixels, and the second electrode may be supplied with another constant voltage different from the constant voltage. According to the configuration above, a display device in which variations in luminance of pixels are reduced in the whole display region can be obtained.

A display device according to a fourteenth aspect of the disclosure in the above first to thirteenth aspects may preferably include an organic EL element as the electro-optic element. According to the configuration above, an organic EL display device in which variations in luminance of pixels are reduced in the whole display region can be obtained.

The disclosure is not limited to each of the embodiments stated above, and various modifications may be implemented within a range not departing from the scope of the claims. Embodiments obtained by appropriately combining technical approaches stated in each of the different embodiments also fall within the scope of the technology of the disclosure. Moreover, novel technical features may be formed by combining the technical approaches stated in each of the embodiments.

### REFERENCE SIGNS LIST

1, 1A to 1C Organic EL display device (display device)
2 Source driver
4, 4C1, 4C2 High level power source circuit (power source circuit)
5, 5C1, 5C2 Power source bus line
6, 6C1, 6C2 Connection line
10 TFT substrate
11 Support body
15, 15A, 15C1, 15C2, 15D High level power source line (power source line)
15a, 15aC1, 15aC2 First end portion
15b, 15bC1, 15bC2 Second end portion
16 Passivation film
17 Interlayer insulating film
25 Edge cover
21 First electrode
22, 22a, 22b Light emitting portion (electro-optic element)
22B, 22aB, 22bB Light emitting portion (electro-optic element)
22C1, 22aC1, 22bC1 Light emitting portion (electro-optic element)
22C2, 22aC2, 22bC2 Light emitting portion (electro-optic element)
23 Second electrode
30 Sealing layer
52 Pixel circuit
53 Voltage conversion circuit
C1 Capacitor
T1 to T6 Transistor

1-4. (canceled)

5. A display device including a display region including pixels disposed in a row direction and a column direction, each of the pixels including a first electrode and a second electrode facing each other with an electro-optic element interposed between the first electrode and the second electrode, the display device comprising:
a power source circuit serving as a supply source of a voltage supplied to the first electrode;
power source lines connected to the power source circuit to be supplied with a constant voltage from the power source circuit; and
pixel circuits respectively disposed in the pixels, each of the pixel circuits including the electro-optic element, the first electrode, and the second electrode, each of the pixel circuits being configured to be supplied with the constant voltage from at least one of the power source lines and to control a signal to be given to the electro-optic element,
wherein each of the power source lines extends along the pixels aligned in the row direction or the column direction, and includes a first end portion being on a first end portion side to be supplied with the constant voltage from the power source circuit and a second end portion being on a second end portion side opposite to the first end portion,
a resistance value per unit length in each of the power source lines is increased from the first end portion side to the second end portion side in at least a part of a section ranging from the first end portion to the second end portion, and
a notch is arranged to adjust the resistance value of each of the power source lines in at least the part of the section.

6. The display device according to claim 5,
wherein in a case where the display region is seen from a normal direction, an area of the notch included in the unit length in a section on the first end portion side, in at least the part of the section, is smaller than an area of the notch included in the unit length in a section on the second end portion side.

7. The display device according to claim 5,
wherein the power source lines are formed in a comb-like shape in which positions of first end portions and second end portions of the power source lines adjacent to each other are reversed.

8. The display device according to claim 5,
wherein, out of the pixels aligned to be adjacent to at least the part of the section in each of the power source lines, an area of the electro-optic element included in a pixel of the pixels on the second end portion side is greater than an area of the electro-optic element included in a pixel of the pixels on the first end portion side.

9. A display device including a display region including pixels disposed in a row direction and a column direction, each of the pixels including a first electrode and a second electrode facing each other with an electro-optic element interposed between the first electrode and the second electrode, the display device comprising:
a power source circuit serving as a supply source of a voltage supplied to the first electrode;
power source lines connected to the power source circuit to be supplied with a constant voltage from the power source circuit; and
pixel circuits respectively disposed in the pixels, each of the pixel circuits including the electro-optic element, the first electrode, and the second electrode, each of the pixel circuits being configured to be supplied with the constant voltage from at least one of the power source lines and to control a signal to be given to the electro-optic element,
wherein each of the power source lines extends along the pixels aligned in the row direction or the column direction, and includes a first end portion being on a first end portion side to be supplied with the constant voltage from the power source circuit and a second end portion being on a second end portion side opposite to the first end portion, and
out of the pixels aligned to be adjacent to at least a part of a section ranging from the first end portion to the second end portion in each of the power source lines, an area of the electro-optic element included in a pixel of the pixels on the second end portion side is greater than an area of the electro-optic element included in a pixel of the pixels on the first end portion side.

10. The display device according to claim 8,
wherein an area gradually increases from the electro-optic element included in the pixel of the pixels on the first end portion side toward the electro-optic element included in the pixel of the pixels on the second end portion side.

11. The display device according to claim 5,
wherein in the power source lines, first end portions adjacent to each other are connected to each other.

12. The display device according to claim 5,
wherein in the power source lines, second end portions adjacent to each other are connected to each other.

13. The display device according to claim 5,
wherein the first electrode is arranged in an island shape for each pixel,
the second electrode is continuously disposed across the pixels, and
the second electrode is supplied with another constant voltage different from the constant voltage.

14. The display device according to claim 5,
wherein the display device comprises an organic EL element as the electro-optic element.

15. The display device according to claim 5,
wherein each of the power source lines has a resistance value gradually reduced from the second end portion toward the first end portion.

16. The display device according to claim 5,
wherein in a case where the display region is seen from a normal direction, in each of the power source lines, an area per the unit length in a section on the first end portion side in at least the part of the section is greater than an area per the unit length in a section on the second end portion side.

17. The display device according to claim 5,
wherein in a case where the display region is seen from a normal direction, in each of the power source lines, a width in a section on the first end portion side in at least the part of the section is greater than a width in a section on the second end portion side.

18. A display device including a display region including pixels disposed in a row direction and a column direction, each of the pixels including a first electrode and a second electrode facing each other with an electro-optic element interposed between the first electrode and the second electrode, the display device comprising:
a power source circuit serving as a supply source of a voltage supplied to the first electrode;
power source lines connected to the power source circuit to be supplied with a constant voltage from the power source circuit; and
pixel circuits respectively disposed in the pixels, each of the pixel circuits including the electro-optic element, the first electrode, and the second electrode, each of the pixel circuits being configured to be supplied with the constant voltage from at least one of the power source lines and to control a signal to be given to the electro-optic element,
wherein each of the power source lines extends along the pixels aligned in the row direction or the column direction, and includes a first end portion being on a first end portion side to be supplied with the constant voltage from the power source circuit and a second end portion being on a second end portion side opposite to the first end portion,
a resistance value per unit length in each of the power source lines is increased from the first end portion side to the second end portion side in at least a part of a section ranging from the first end portion to the second end portion, and
the power source lines are formed in a comb-like shape in which positions of the first end portions and the second end portions of the power source lines adjacent to each other are reversed.

19. The display device according to claim 18,
wherein each of the power source lines has a resistance value gradually reduced from the second end portion toward the first end portion.

20. The display device according to claim 18,
wherein in a case where the display region is seen from a normal direction, in each of the power source lines, an area per the unit length in a section on the first end portion side in at least the part of the section is greater than an area per the unit length in a section on the second end portion side.

21. The display device according to claim 18,
wherein in a case where the display region is seen from a normal direction, in each of the power source lines, a width in a section on the first end portion side in at least the part of the section is greater than a width in a section on the second end portion side.

22. The display device according to claim 18,
wherein in a case where the display region is seen from a normal direction, an area of the notch included in the unit length in a section on the first end portion side, in at least the part of the section is smaller than an area of the notch included in the unit length in the section on the second end portion side.

23. The display device according to claim 18,
wherein, out of the pixels aligned to be adjacent to at least the part of the section in each of the power source lines, an area of the electro-optic element included in a pixel of the pixels on the second end portion side is greater than an area of the electro-optic element included in a pixel of the pixels on the first end portion side.

24. The display device according to claim 9,
wherein an area gradually increases from the electro-optic element included in the pixel of the pixels on the first end portion side toward the electro-optic element included in the pixel of the pixels on the second end portion side.
